(19) United States
(12) Patent Application Publication
(10) Pub. No.: US 2014/0030656 A1
(43) Pub. Date: Jan. 30, 2014

(54) METHOD FOR FORMING RESIST PATTERNS AND METHOD FOR PRODUCING PATTERNED SUBSTRATES

(71) Applicant: Fujifilm Corporation, Tokyo (JP)

(72) Inventors: Toshihiro USA, Haibara-gun (JP); Toru TSUCHIHASHI, Haibara-gun (JP)

(73) Assignee: Fujifilm Corporation, Tokyo (JP)

(21) Appl. No.: 14/040,171

(22) Filed: Sep. 27, 2013

Related U.S. Application Data
(63) Continuation of application No. PCT/JP2012/002034, filed on Mar. 23, 2012.

(30) Foreign Application Priority Data
Mar. 30, 2011 (JP) 2011-075219

(51) Int. Cl. G03F 7/20

(52) U.S. Cl. CPC G03F 7/20
USPC 430/296

(57) ABSTRACT

A method for forming a resist pattern that includes a layout having a minimum line width of 100 nm or less forms a resist film on a substrate, draws a lithography pattern on the resist film with a variable shape electron beam, and executes puddle development on the resist film such that the film reduction rate of the resist film at undissolved resist portions is 20% or less. Thereby, shifting from designs of lithography patterns due to switching operations of lithography apparatuses when forming resist patterns that include layouts with minimum line widths of 100 nm or less can be prevented.

### TECHNICAL FIELD

The present invention is related to a method for forming a resist pattern having a predetermined pattern of protrusions and recesses, and a method for producing a patterned substrate that employs the method for forming a resist pattern.

### BACKGROUND ART

Nanoimprinting is a development of the well known embossing technique employed to produce optical discs. In the nanoimprinting method, a mold (commonly referred to as a mold, a stamper, or a template), on which a pattern of protrusions and recesses is formed, is pressed against resist coated on a substrate, which is an object to be processed. Pressing of the original onto the resist causes the resist to mechanically deform or to flow, to precisely transfer the fine pattern.

Presently, application of nanoimprinting to form semiconductor devices having complex circuit structures is being considered. There are expectations that the costs for producing semiconductor devices can be significantly reduced in the case that nanoimprinting is applied to form circuit patterns of the semiconductor devices.

The invention of Japanese Unexamined Patent Publication No. 2008-265028 is an example in which nanoimprinting is applied to form the circuit pattern of a semiconductor device. The range of line widths of circuit patterns of semiconductor devices is wide, from several tens of nanometers to several micrometers. Generally, patterns of protrusions and recesses on molds are produced by using resist films, on which patterns of protrusions and recesses corresponding to the circuit patterns have been formed, as masks, and by etching the surfaces of substrates that become the molds. Accordingly, the ranges of line widths of the patterns of protrusions and recesses formed on the resist films will also be wide, corresponding to the aforementioned range. The invention of Japanese Unexamined Patent Publication No. 2008-265028 takes these circumstances into consideration, and draws a lithography pattern corresponding to a circuit pattern on a resist film by using a spot electron beam lithography apparatus in a first drawing region at which the line width of the lithography pattern is 100 nm or less and by using a variable shape electron beam lithography apparatus in a second drawing region at which the line width of the lithography pattern is greater than 100 nm. According to the method disclosed in Japanese Unexamined Patent Publication No. 2008-265028, the pattern within the first drawing region can be drawn with high precision, while the processing performance of the lithography process as a whole can be improved.

### DISCLOSURE OF THE INVENTION

However, in the method of Japanese Unexamined Patent Publication No. 2008-265028, it is necessary to switch the spot electron beam lithography apparatus and the variable shape electron beam lithography apparatus. In the case that the accuracy in overlap of lithography patterns to be drawn by each lithography apparatus is low, there is a possibility that the lithography pattern will deviate from the design thereof due to the switching operation. Further, there is a possibility that the lithography pattern will be broken.

The present invention has been developed in view of the foregoing circumstances. It is an object of the present invention to provide a method for forming a resist pattern capable of preventing deviation from designs of lithography patterns due to switching operations of lithography apparatuses when forming resist patterns that include layouts with minimum line widths of 100 nm or less.

Further, it is an object of the present invention to provide a method for producing a patterned substrate by etching a substrate using a resist pattern as a mask, in which the processing accuracy of a pattern of protrusions and recesses corresponding to the resist pattern is improved.

A method for forming a resist pattern of the present invention that achieves the above object is a method for forming a resist pattern that includes a layout having a minimum line width of 100 nm or less, comprising:

forming a resist film on a substrate;

drawing a lithography pattern on the resist film with a variable shape electron beam; and

executing puddle development on the resist film such that the film reduction rate of the resist film at undissolved resist portions is 20% or less.

In the present specification, the term “minimum line width” refers to the minimum line width within a pattern layout.

The term “undissolved resist portions” refer to portions of the resist film within a region which is completely uninfluenced by a drawing electron beam in the case that a positive resist is employed, and refers to portions of the resist film within a region which is influenced by the drawing electron beam in the case that a negative resist is employed.

The “film reduction rate” refers to the percentage of the difference in thickness of the undissolved resist portions of the resist film prior to and following development with respect to the thickness of the undissolved resist portions prior to development.

In the method for forming a resist pattern of the present invention, it is preferable for:

the development time for the puddle development to be within a range from 15 seconds to 60 seconds.

In the method for forming a resist pattern of the present invention, it is preferable for:

the diluted concentration of a developing fluid for the puddle development to be within a range from 20% to 90%.

In the method for forming a resist pattern of the present invention, it is preferable for:

the temperature during the puddle development to be within a range from 2° C. to 20° C.

In the method for forming a resist pattern of the present invention, it is preferable for:

a developing fluid to be employed in the puddle development to not contain activating agents.

In the method for forming a resist pattern of the present invention, it is preferable for:

the resist to contain one of a compound represented by General Formula (1) and a compound represented by General Formula (2) below.

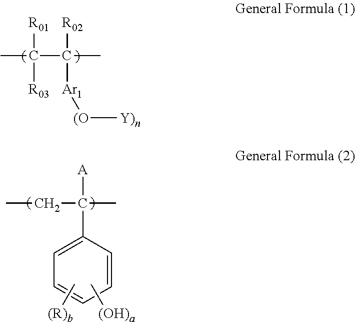

In General Formula (1), each of R₀₁, R₀₂, and R₀₃ independently represents one of a hydrogen atom, an alkyl group, a cycloalkyl group, a halogen atom, a cyano group and an alkoxycarbonyl group. Ar₁ represents an aromatic ring group, for example. Note that R₀₃ and Ar₁ may represent alkylene groups that bond with each other that form one of a five membered ring and a six membered ring with the —C—C— chain. The n number of Y each represents an independent group that desorbs by operations of hydrogen atoms or acids. At least one of Y represents a group that desorbs by operation of an acid. n represents an integer within a range from 1 to 4, preferably an integer within a range from 1 to 2, and more preferably, 1.

In General Formula (2), A represents one of a hydrogen atom, an alkyl group, a cycloalkyl group, a halogen atom, and a cyano group, R represents one of a halogen atom, an alkyl group, a cycloalkyl group, an aryl group, an alkenyl group, an aralkyl group, an alkoxy group, an alkylcarbonyloxy group, and an alkylsulfonyloxy group, which may be the same or different in the case that a plurality of R exists, and which may bond with each other to form rings, a represents an integer within a range from 1 to 3, and b represents an integer within a range from 0 to 3-a.

A method for producing a patterned substrate of the present invention comprises:

forming a resist pattern on a resist film on a substrate by the method described above; and

forming a pattern of protrusions and recesses corresponding to the resist pattern, by etching the substrate using the resist film, on which the resist pattern has been formed, as a mask.

The method for forming a resist pattern of the present invention is a method for forming a resist pattern that includes a layout having a minimum line width of 100 nm or less, comprising: forming a resist film on a substrate; drawing a lithography pattern on the resist film with a variable shape electron beam; and executing puddle development on the resist film such that the film reduction rate of the resist film at undissolved resist portions is 20% or less. The present inventors found that portions of resist film at hem field regions of electron beams (regions in which the intensity profiles of electron beams have hems) being completely removed by development can be prevented in the case that the film reduction rate of the undissolved resist portions is 20% or less. Accordingly, a resist pattern having desired line widths can be formed even by drawing a lithography pattern that includes a layout having a minimum line width of 100 nm or less, by the method for forming a resist pattern of the present invention. As a result, the need to switch from a spot electron beam lithography apparatus to a variable shape electron beam lithography apparatus is obviated, and a lithography pattern can be drawn using only the variable shape electron beam lithography apparatus. Therefore, deviation from designs of lithography patterns due to switching operations of lithography apparatuses when forming resist patterns that include layouts with minimum line widths of 100 nm or less can be prevented.

The method for producing a patterned substrate of the present invention forms a resist pattern on a substrate by the method of the present invention described above, and forms a pattern of protrusions and recesses corresponding to the resist pattern by etching the substrate using the resist film, on which the resist pattern has been formed, as a mask. Accordingly, deviations from designs of lithography patterns due to switching operations of lithography apparatuses when drawing on the resist film can be prevented. As a result, processing accuracy of patterns of protrusions and recesses corresponding to resist patterns can be improved in the production of patterned substrates by etching the substrates having the resist patterns thereon.

### BRIEF DESCRIPTION OF THE DRAWINGS

FIG. 1 is a sectional diagram that schematically illustrates the relationship between the intensity profile of an electron beam and drawing on a resist film.

FIG. 2A is a sectional diagram that schematically illustrates a mold obtained by the method for producing a patterned substrate of the present invention.

FIG. 2B is a magnified view that schematically illustrates the cross section of a portion of a patterned region of the mold of FIG. 2A.

FIG. 3 is a graph that illustrates the relationship between development conditions and film reduction rates.

### BEST MODE FOR CARRYING OUT THE INVENTION

Hereinafter, embodiments of the present invention will be described with reference to the attached drawings. However, the present invention is not limited to the embodiments to be described below. Note that the dimensional scale ratios, etc. of the constituent elements within the drawings are not necessarily as the actual scale ratios in order to facilitate visual understanding.

### [Method for Forming a Resist Pattern]

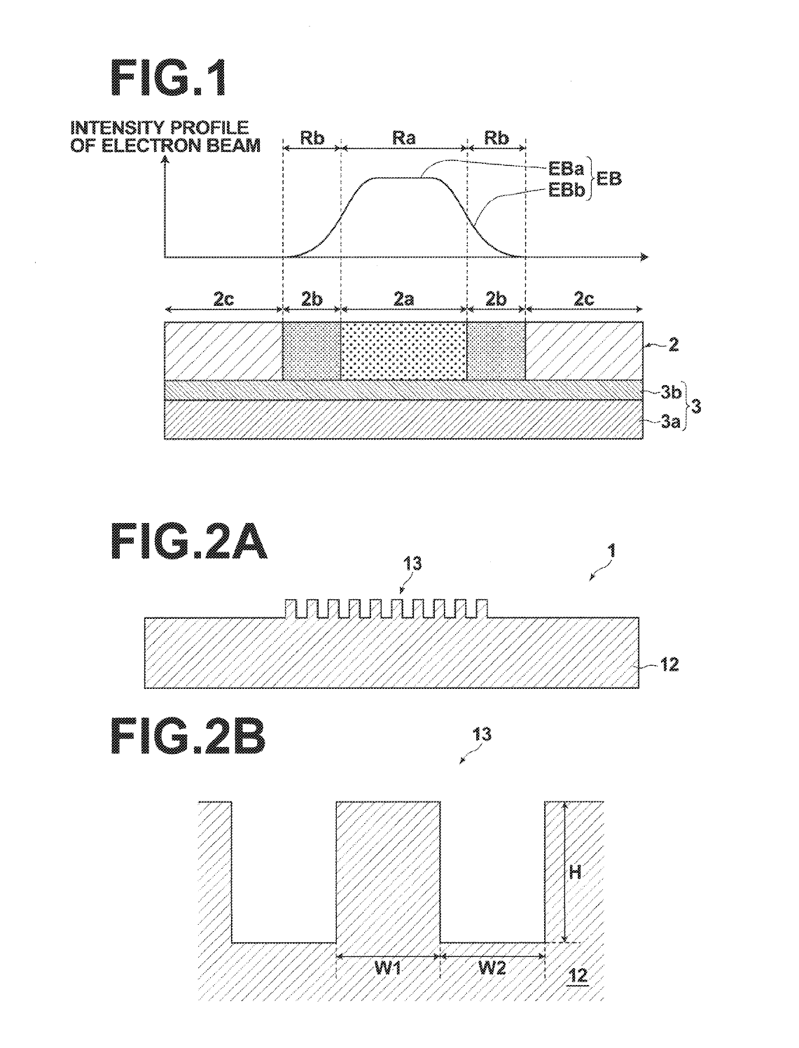

First, an embodiment of a method for forming a resist pattern (a pattern of protrusions and recesses formed by resist) will be described. FIG. 1 is a sectional diagram that schematically illustrates the relationship between the intensity profile of an electron beam and drawing on a resist film.

The method for forming a resist pattern of the present embodiment coats resist onto a substrate 3 to form a resist film, draws a lithography pattern that includes a layout having a minimum line width of 100 nm or less on the resist film with a variable shape electron beam, and executes puddle development on the resist film such that the film reduction rate of undissolved resist portions is 20% or less.

The substrate 3 is a base for a patterned substrate, on the surface of which a pattern of protrusions and recesses is formed. The substrate 3 is patterned by a method for producing a patterned substrate to be described later to become a patterned substrate. The shape, structure, size, material, etc. of the substrate 3 is not particularly limited, and may be selected as appropriate according to the intended use thereof. The surface of the substrate 3 on which the pattern of protrusions and recesses is to be formed is the surface on which the resist is coated. The substrate 3 may be a 6 inch silicon wafer or a 6025 mask blank, for example. The substrate 3 may be of a single layer structure or a laminated structure. The material of the substrate may be selected from among known materials. Examples of such known materials include: metal materials such as silicon, nickel, and aluminum; glass materials such as quartz; and resin. These materials may be utilized singly or in combinations of two or more. The thickness of the substrate 3 is not particularly limited, and may be selected as appropriate according to the intended use thereof.

It is preferable for the substrate 3 to have one or more mask layers on the surface thereof on which the resist is coated. In this case, the substrate 3 is constituted by a support substrate 3a and a mask layer 3b as illustrated in FIG. 1. The mask layer 3b functions as a mask when the support substrate 3a is etched as will be described later. The material of the mask layer 3b is selected from materials that will decrease etching selectivity of the mask layer 3b with respect to the support substrate 3a. Preferred examples of the material of the mask layer 3b include: metal materials such as chrome, tungsten, titanium, nickel, silver, platinum, and gold; and metal oxide materials such as chrome oxide, tungsten oxide, and titanium oxide. Further, it is preferable for the mask layer 3b to include at least one layer that contains chrome and/or chrome oxide.

The surface of the substrate 3 may undergo a surface process by a silane coupling agent, HMDS (Hexa Methyl Di Silazane) in order to increase adhesive properties with the resist.

The resist film 2 is constituted by a chemically amplified resist that becomes soluble into developing fluid by irradiation of an electron beam. The resist film 2 is formed by spin coating a resist liquid onto the substrate 3, for example. The resist is not particularly limited. PRL009 by FUJIFILM Electronics Materials, a resin that contains a compound represented by General Formula (1) below, or a resin that contains a compound represented by General Formula (2) below can be favorably employed.

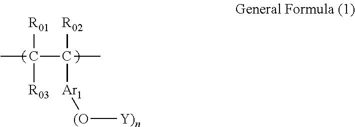

In General Formula (1), each of R₀₁, R₀₂, and R₀₃ independently represents one of a hydrogen atom, an alkyl group, a cycloalkyl group, a halogen atom, a cyano group and an alkoxycarbonyl group. Ar₁ represents an aromatic ring group, for example. Note that R₀₃ and Ar₁ may represent alkylene groups that bond with each other that form one of a five membered ring and a six membered ring with the —C—C— chain. The n number of Y each represents an independent group that desorbs by operations of hydrogen atoms or acids. At least one of Y represents a group that desorbs by operation of an acid. n represents an integer within a range from 1 to 4, preferably an integer within a range from 1 to 2, and more preferably, 1.

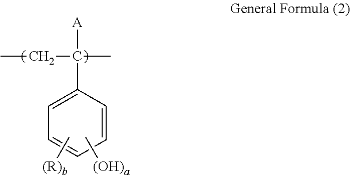

In General Formula (2), A represents one of a hydrogen atom, an alkyl group, a cycloalkyl group, a halogen atom, and a cyano group, R represents one of a halogen atom, an alkyl group, a cycloalkyl group, an aryl group, an alkenyl group, an aralkyl group, an alkoxy group, an alkylcarbonyloxy group, and an alkylsulfonyloxy group, which may be the same or different in the case that a plurality of R exists, and which may bond with each other to form rings, a represents an integer within a range from 1 to 3, and b represents an integer within a range from 0 to 3-a.

Drawing of the lithography pattern is executed using a variable shape electron beam lithography apparatus. The variable shape electron beam lithography apparatus is an apparatus that causes an electron beam output from an electron gun (emitter) to pass through a rectangular hole called a shaping aperture to change the shape of the electron beam to a rectangle, and continuously irradiates the rectangular electron beam synchronized with movement of an x-y stage to perform pattern lithography. Electron beam irradiation ranges can be adjusted into various shapes by changing the transmissive area of the hole of the shaping aperture in the variable shape electron beam lithography apparatus. The processing performance of the variable shape electron beam lithography apparatus is extremely high, approximately 100 times that of a spot electron beam lithography apparatus. Therefore, the processing performance of the lithography process as a whole can be significantly improved by executing the lithography process employing only the variable shape electron beam lithography apparatus. The resist film is drawn on by the electron beam, which is shaped to match the designed light widths at each location within the lithography pattern. An example of such a variable shape electron beam lithography apparatus that can be utilized is EBM-6000 by K. K. NuFlare.

The resist is developed by puddle development. In puddle development, developing fluid is supplied to the resist film on the surface of the substrate, and the surface tension thereof is utilized to cover the entirety of the surface of the resist film. Thereafter, supply of the developing fluid is ceased, and the resist film is developed while the substrate is laid still or rotated at a speed sufficiently slow such that the developing fluid does not fly off the resist film. Note that the developing fluid is removed by administering a rinsing process using purified water following puddle development. In addition, the developing fluid may be supplied a plurality of times during puddle development. Specifically, a first scan by a developing fluid supplying means to cover the entire surface of the resist film with the developing fluid is executed, and then a second scan may be executed after a predetermined amount of time elapses thereafter. Here, the number of scanning operations by the developing fluid supplying mean sis not particularly limited. Puddle development is advantageous in that (1) the amount of developing fluid which is utilized can be decreased, and (2) development defects can be suppressed, thereby realizing decreases in cost and performance deterioration compared to the immersion development method. An example of such a puddle developing apparatus that can be utilized is the MaskTrack developing apparatus by HamaTech.

In the present invention, puddle development is executed such that the film reduction rate at undissolved resist portions of the resist film is 20% or less. As described previously, the film reduction rate is the percentage of the difference in thickness of the undissolved resist portions of the resist film prior to and following development with respect to the thickness of the same undissolved resist portions prior to development. That is, if the thickness of an undissolved resist portion of the resist film prior to development is designated as A, and the thickness of the same undissolved resist portion following development is designated as B, the film reduction rate is represented by (A−B)/A.

The film reduction rate is adjusted by controlling conditions during puddle development as appropriate. Examples of conditions during puddle development include: development time (the amount of time that the resist is exposed to the developing fluid), the concentration of the developing fluid, the presence or absence of activating agents in the developing fluid, the fluid temperature during development, and the number of times the developing fluid supply means performs scanning. In the case that adjustments are administered to decrease the film reduction rate, the development time is shortened, the concentration of the developing fluid is decreased, activating agents are not utilized within the developing fluid, the temperature during development is decreased, and the number of scanning operations by the developing fluid supply means is decreased, for example. In the case that tetramethylammonium hydroxide (TMAH) 2.38& alkaline developing fluid is utilized as the developing fluid, for example, it is preferable to utilize NMD-3 by Tokyo Applied Chemical Industries that does not contain activating agents over NMD-W, also by Tokyo Applied Chemical Industries, that contains activating agents. It is preferable for the development time to be within a range from 15 seconds to 60 seconds. It is preferable for the diluted concentration of the developing fluid to be within a range from 20% to 90%. In addition, the number of scanning operations by the developing fluid supply means is preferably once or twice, because it is preferable for development to be performed while the developing fluid is maintained in a still state, as will be described later.

Hereinafter, the operation of the present invention will be described.

A variable shape electron beam EB is shaped into a rectangle by the shaping aperture. However, the intensity profile of the electron beam EB has slight hems within regions outside the rectangular shape (FIG. 1). Accordingly, the resist film 2 is drawn by an electron beam EBa within a shaped region Ra at which the intensity profile is comparatively uniform, and by electron beams EBb at hem field regions Rb. Normally, the width of the shaped region Ra is set to match the line with of a lithography pattern. Therefore, a portion 2a of the resist film 2 drawn by the electron beam EBa at the shaped region Ra becomes a desired line width of the lithography pattern. For this reason, it is important for development to be executed such that portions 2b of the resist film 2 which are drawn by the electron beams EBb at the hem field regions Rb remain, in order to obtain a lithography pattern according to the design thereof utilizing the variable shape electron beam EB.

As the result of intensive study by the present inventors, it was found that the film reduction rate of undissolved resist portions 2c of the resist film 2 was an effective index that represents the degree of development. It was confirmed that the portions 2b of the resist film 2 drawn by the electron beams EBb at the hem field regions Rb being completely removed could be prevented, if development was executed such that the film reduction rate was 20% or less. Note that when actually executing puddle development, a resist film which has not been drawn by lithography is employed to obtain the relationship between film reduction rates and development conditions.

As described above, the method for forming a resist pattern of the present invention is capable of forming a resist pattern having desired line widths even if a lithography pattern that includes a layout having a minimum line width of 100 nm or less is drawn by a variable shape electron beam. As a result, the need to switch from a spot electron beam lithography apparatus to a variable shape electron beam lithography apparatus is obviated, and a lithography pattern can be drawn using only the variable shape electron beam lithography apparatus. Therefore, deviation from designs of lithography patterns due to switching operations of lithography apparatuses when forming resist patterns that include layouts with minimum line widths of 100 nm or less can be prevented.

Further, the method for forming a resist pattern of the present invention employs the variable shape electron beam lithography apparatus having high lithography processing performance. Therefore, the processing performance of the lithography process as a whole can be improved compared to the method disclosed in Japanese Unexamined Patent Publication No. 2008-265028.

### [Method for Producing a Patterned Substrate]

Next, an embodiment of a method for producing a patterned substrate of the present invention will be described. In the present embodiment, a patterned substrate is produced employing the method for forming a resist pattern described above.

First, the method for forming a resist pattern described above is employed to form a resist film having a desired pattern of protrusions and recesses. Next, a substrate is etched using the resist film having the pattern formed thereon as a mask, to form a pattern of protrusions and recesses corresponding to the pattern of protrusions and recesses of the resist film, to obtain a patterned substrate having the predetermined pattern of protrusions and recesses on the surface thereof. The patterned substrate may be utilized as a nanoimprinting mold itself, or as an original plate for producing such a mold.

Meanwhile, in the case that the substrate to be processed is of a laminated structure and includes the mask layer 3b on the surface thereof, the resist film 2, on which a predetermined pattern has been formed by the method for forming a resist pattern described above, is formed on the surface of the substrate 3 having the mask layer 3b. Then, dry etching is performed using the resist film 2 as a mask, to form a pattern of protrusions and recesses corresponding to the pattern of protrusions and recesses of the resist film in the mask layer 3b. Thereafter, dry etching is further performed with the mask layer 3b as an etching stop layer, to form a pattern of protrusions and recesses in the substrate 3. Thereby, a patterned substrate having the predetermined pattern is obtained.

The dry etching method is not particularly limited as long as it is capable of forming a pattern of protrusions and recesses in the substrate, and may be selected according to intended use. Examples of dry etching methods that may be employed include: the ion milling method; the RIE (Reactive Ion Etching) method; the sputter etching method; etc. From among these methods, the ion milling method and the RIE method are particularly preferred.

A fluorine series gas or a chlorine series gas may be employed as an etchant in the RIE method.

As described above, the method for producing a patterned substrate of the present invention can prevent deviation from a lithography pattern due to switching of lithography apparatuses when drawing on the resist. As a result, processing accuracy of patterns of protrusions and recesses corresponding to resist patterns can be improved in the production of patterned substrates by etching the substrates having the resist patterns thereon.

A mold 1 produced by the method described above is constituted by a support portion 12 and a pattern 13 of fine protrusions and recesses formed on the surface of the support portion 12 as illustrated in FIG. 2A and FIG. 2B, for example.

Examples of the material of the support portion 12 include: metal materials such as silicon, nickel, aluminum, chrome, steel, tantalum, and tungsten; and oxides, nitrides, and carbides thereof. Specific examples of the material of the support portion 12 include: silicon oxide, aluminum oxide, quartz glass Pyrex™, and soda glass.

The shape of the pattern 13 of protrusions and recesses is not particularly limited, and is selected as appropriate according to the intended use thereof. A typical pattern is the line and space pattern illustrated in FIG. 2A and FIG. 2B. The length of the protrusions, the width W1 of the protrusions, the distance W2 among the protrusions, and the height H of the protrusions from the bottoms of the recesses (the depth of the recesses) are set as appropriate in the line and space pattern. For example, the width W1 of the protrusions is within a range from 10 nm to 100 nm, more preferably within a range from 20 nm to 70 nm, the distance W2 among the protrusions is within a range from 10 nm to 100 nm, more preferably within a range from 20 nm to 100 nm, and the height H of the protrusions is within a range from 10 nm to 500 nm, more preferably within a range from 30 nm to 100 nm. In addition, the shape of the pattern 13 of protrusions and recesses may be that in which dots having rectangular, circular, and elliptical cross sections are arranged.

### EXAMPLES

Examples of the method for forming a resist pattern of the present invention will be described below.

<Relationship between Development Conditions and Film Reduction Rate>

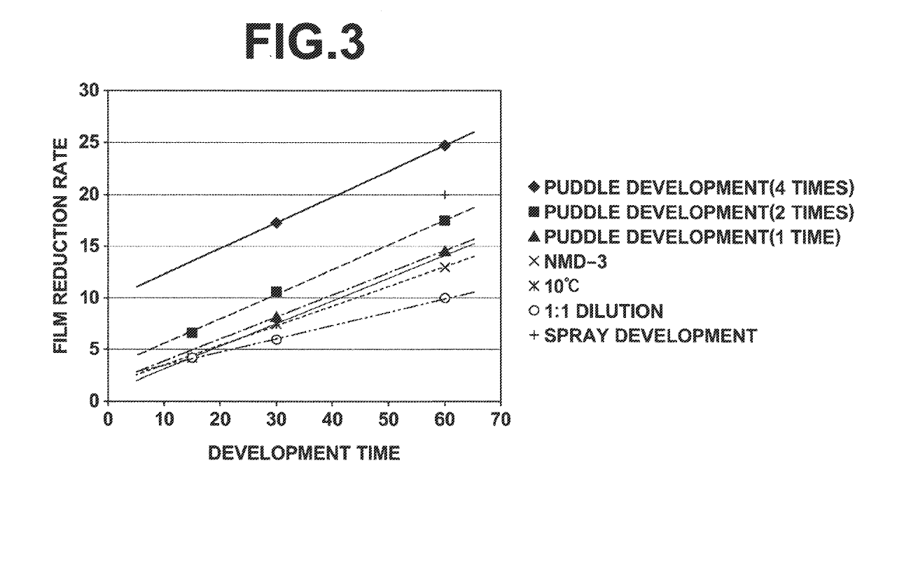

First, film reduction rates were calculated under different development conditions for a case in which the resist is Compound A represented by General Formula (1). FIG. 3 is a graph that illustrates the relationship between development conditions and film reduction rates. In the graph of FIG. 3, plots denoted by “Puddle Development (4 times)” are data for cases in which the developing technique is puddle development, the developing fluid is supplied four times, the developing fluid is TMAH 2.38% that contains activating agents, and the temperature of the developing fluid is 23° C. Plots denoted by “Puddle Development (2 times)” are data for cases in which the developing technique is puddle development, the developing fluid is supplied two times, the developing fluid is TMAH 2.38% that contains activating agents, and the temperature of the developing fluid is 23° C. Plots denoted by “Puddle Development (1 time)” are data for cases in which the developing technique is puddle development, the developing fluid is supplied one time, the developing fluid is TMAH 2.38% that contains activating agents, and the temperature of the developing fluid is 23° C. Plots denoted by “NMD-3” are data for cases in which the developing technique is puddle development, the developing fluid is supplied one time, the developing fluid is TMAH 2.38% that does not contain activating agents, and the temperature of the developing fluid is 23° C. Plots denoted by “10° C.” are data for cases in which the developing technique is puddle development, the developing fluid is supplied one time, the developing fluid is TMAH 2.38% that contains activating agents, and the temperature of the developing fluid is 10° C. Plots denoted by “1:1 Dilution” are data for cases in which the developing technique is puddle development, the developing fluid is supplied one time, the developing fluid is TMAH 2.38% that contains activating agents mixed with an equal amount of pure water rinsing liquid, and the temperature of the developing fluid is 23° C.

### Example 1

Resist was coated on a substrate to form a resist film, a predetermined line and space pattern was drawn on the resist film using a variable shape electron beam (VSB), and then the resist film was developed. The best resolution (the minimum line width of the line and space pattern when a pattern preferable for practical use is formed) that can be obtained under these conditions was investigated. In the present example, the resist was compound A represented by General Formula (1), the developing fluid was TMAH 2.38% that contains activating agents, the developing technique was puddle development in which the developing fluid was supplied once, the temperature of the developing fluid was 23° C., and the development time was 30 seconds.

### Example 2

All conditions were the same as those for Example 1, except that the development time was 15 seconds.

### Example 3

All conditions were the same as those for Example 2, except that the developing fluid did not contain activating agents.

### Example 4

All conditions were the same as those for Example 2, except that the temperature of the developing fluid was 10° C.

### Example 5

All conditions were the same as those for Example 2, except that the concentration of TMAH in the developing fluid was 1.19% and that the development time was 30 seconds.

### Comparative Example 1

All conditions were the same as those for Example 1, except that the developing fluid was supplied four times during puddle development, and the development time was 60 seconds.

### Comparative Example 2

All conditions were the same as those for Comparative Example 1, except that the developing technique was spray development.

### Comparative Example 3

All conditions were the same as those for Comparative Example 2, except that the resist was PRL009.

### <Results>

Table 1 below shows the development conditions and the resolutions of Examples 1 through 5 and Comparative Examples 1 through 3. These results confirm that it is possible to form resist patterns that include layouts having a minimum line width of 100 nm or less using only a variable shape electron beam, under development conditions that result in film reduction rates of undissolved resist portions of resist films being 20% or less.

TABLE 1

| | Resist | Lithography | | | | | |
|---|---|---|---|---|---|---|---|
| | Type | Method | Development Conditions | | | | Resolution |
| Example 1 | Resist A | VSB | TMAH 2.38% | Puddle | 23° C. | 30 sec | 53 nm |
| | | | with activating | Development | | | |
| | | | agents | 1 Scan | | | |
| Example 2 | Resist A | VSB | TMAH 2.38% | Puddle | 23° C. | 15 sec | 33 nm |
| | | | with activating | Development | | | |
| | | | agents | 1 Scan | | | |
| Example 3 | Resist A | VSB | TMAH 2.38% | Puddle | 23° C. | 15 sec | 29 nm |
| | | | without activating | Development | | | |
| | | | agents | 1 Scan | | | |
| Example 4 | Resist A | VSB | TMAH 2.38% | Puddle | 10° C. | 15 sec | 26 nm |
| | | | with activating | Development | | | |
| | | | agents | 1 Scan | | | |
| Example 5 | Resist A | VSB | TMAH 1.19% | Puddle | 23° C. | 30 sec | 26 nm |
| | | | with activating | Development | | | |
| | | | agents | 1 Scan | | | |
| Comparative | Resist A | VSB | TMAH 2.38% | Puddle | 23° C. | 60 sec | 112 nm |
| Example 1 | | | with activating | Development | | | |
| | | | agents | 4 Scans | | | |
| Comparative | Resist A | VSB | TMAH 2.38% | Spray | 23° C. | 60 sec | 101 nm |
| Example 2 | | | with activating | Development | | | |
| | | | agents | | | | |
| Comparative | PRL009 | VSB | TMAH 2.38% | Spray | 23° C. | 60 sec | 118 nm |
| Example 3 | | | with activating | Development | | | |
| | | | agents | | | | |

What is claimed is:

1. A method for forming a resist pattern that includes a layout having a minimum line width of 100 nm or less, comprising:
obtaining a relationship between a film reduction rate and development conditions employing a first resist film constituted by a positive type resist material;
forming a second resist film constituted by the same resist material as that of the first resist film on a substrate;
drawing a lithography pattern on the second resist film with a variable shape electron beam; and
executing puddle development on the second resist film under development conditions based on the obtained relationship such that the film reduction rate of the second resist film at undissolved resist portions is 20% or less.

2. A method for forming a resist pattern as defined in claim 1, wherein:
the development time for the puddle development is within a range from 15 seconds to 60 seconds.

3. A method for forming a resist pattern as defined in claim 1, wherein:
the diluted concentration of a developing fluid for the puddle development is within a range from 20% to 90%.

4. A method for forming a resist pattern as defined in claim 2, wherein:
the diluted concentration of a developing fluid for the puddle development is within a range from 20% to 90%.

5. A method for forming a resist pattern as defined in claim 1, wherein:
the temperature during the puddle development is within a range from 2° C. to 20° C.

6. A method for forming a resist pattern as defined in claim 2, wherein:
the temperature during the puddle development is within a range from 2° C. to 20° C.

7. A method for forming a resist pattern as defined in claim 1, wherein:
a developing fluid to be employed in the puddle development does not contain activating agents.

8. A method for forming a resist pattern as defined in claim 2, wherein:
a developing fluid to be employed in the puddle development does not contain activating agents.

9. A method for forming a resist pattern as defined in claim 1, wherein:
the resist material contains one of a compound represented by General Formula 1 below, in which each of R₀₁ and R₀₂ independently represents one of a hydrogen atom, an alkyl group, a cycloalkyl group, a halogen atom, a cyano group and an alkoxycarbonyl group, R₀₃ represents one of a hydrogen atom, an alkyl group, a cycloalkyl group, a halogen atom, a cyano group, and an alkoxycarbonyl group, Ar₁ represents an aromatic ring group, or R₀₃ and Ar₁ represents alkylene groups that bond with each other and represent one of a five membered ring and a six membered ring, the n number of Y each represents an independent group that desorbs by operations of hydrogen atoms or acids, and n represents an integer within a range from 1 to 4, and a compound represented by General Formula 2 below, in which A represents one of a hydrogen atom, an alkyl group, a cycloalkyl group, a halogen atom, and a cyano group, R represents one of a halogen atom, an alkyl group, a cycloalkyl group, an aryl group, an alkenyl group, an aralkyl group, an alkoxy group, an alkylcarbonyloxy group, and an alkylsulfonyloxy group, which may be the same or different in the case that a plurality of R exists, and which may bond with each other to form rings, a represents an integer within a range from 1 to 3, and b represents an integer within a range from 0 to 3-a.

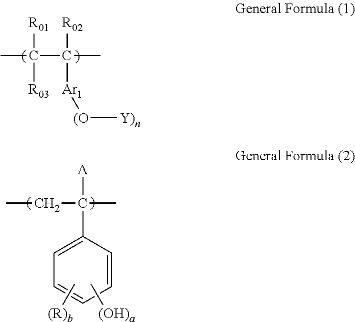

10. A method for forming a resist pattern as defined in claim 2, wherein:
the resist material contains one of a compound represented by General Formula 1 below, in which each of R₀₁ and R₀₂ independently represents one of a hydrogen atom, an alkyl group, a cycloalkyl group, a halogen atom, a cyano group and an alkoxycarbonyl group, R₀₃ represents one of a hydrogen atom, an alkyl group, a cycloalkyl group, a halogen atom, a cyano group, and an alkoxycarbonyl group, Ar₁ represents an aromatic ring group, or R₀₃ and Ar₁ represents alkylene groups that bond with each other and represent one of a five membered ring and a six membered ring, the n number of Y each represents an independent group that desorbs by operations of hydrogen atoms or acids, and n represents an integer within a range from 1 to 4, and a compound represented by General Formula 2 below, in which A represents one of a hydrogen atom, an alkyl group, a cycloalkyl group, a halogen atom, and a cyano group, R represents one of a halogen atom, an alkyl group, a cycloalkyl group, an aryl group, an alkenyl group, an aralkyl group, an alkoxy group, an alkylcarbonyloxy group, and an alkylsulfonyloxy group, which may be the same or different in the case that a plurality of R exists, and which may bond with each other to form rings, a represents an integer within a range from 1 to 3, and b represents an integer within a range from 0 to 3-a.

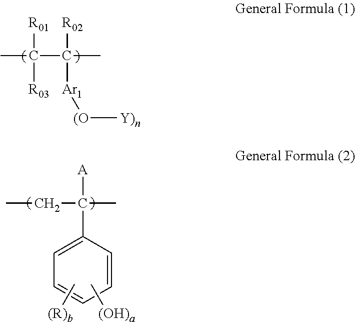

11. A method for forming a resist pattern as defined in claim 3, wherein:
the resist material contains one of a compound represented by General Formula 1 below, in which each of R₀₁ and R₀₂ independently represents one of a hydrogen atom, an alkyl group, a cycloalkyl group, a halogen atom, a cyano group and an alkoxycarbonyl group, R₀₃ represents one of a hydrogen atom, an alkyl group, a cycloalkyl group, a halogen atom, a cyano group, and an alkoxycarbonyl group, Ar₁ represents an aromatic ring group, or R₀₃ and Ar₁ represents alkylene groups that bond with each other and represent one of a five membered ring and a six membered ring, the n number of Y each represents an independent group that desorbs by operations of hydrogen atoms or acids, and n represents an integer within a range from 1 to 4, and a compound represented by General Formula 2 below, in which A represents one of a hydrogen atom, an alkyl group, a cycloalkyl group, a halogen atom, and a cyano group, R represents one of a halogen atom, an alkyl group, a cycloalkyl group, an aryl group, an alkenyl group, an aralkyl group, an alkoxy group, an alkylcarbonyloxy group, and an alkylsulfonyloxy group, which may be the same or different in the case that a plurality of R exists, and which may bond with each other to form rings, a represents an integer within a range from 1 to 3, and b represents an integer within a range from 0 to 3-a.

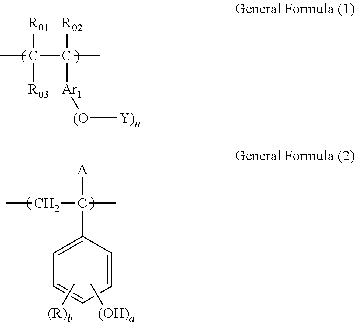

12. A method for producing a patterned substrate, comprising:
forming a resist pattern on a resist film on a substrate by the method as defined in claim 1; and
forming a pattern of protrusions and recesses corresponding to the resist pattern, by etching the substrate using the resist film, on which the resist pattern has been formed, as a mask.
